(19) United States
(12) Patent Application Publication
(10) Pub. No.: US 2011/0031573 A1
(43) Pub. Date: Feb. 10, 2011

(54) SOLID-STATE IMAGING DEVICE, IMAGING APPARATUS, AND MANUFACTURING METHOD OF SOLID-STATE IMAGING DEVICE

(75) Inventor: Masanori NAGASE, Miyagi (JP)

Correspondence Address: KIMBLE INTELLECTUAL PROPERTY LAW, PLLC, 1701 PENNSYLVANIA AVE., NW, SUITE 300, WASHINGTON, DC, 20006, US

(73) Assignee: FUJIFILM Corporation, Tokyo (JP)

(21) Appl. No.: 12/699,862

(22) Filed: Feb. 3, 2010

(30) Foreign Application Priority Data
Feb. 4, 2009 (JP) 2009-023662

(51) Int. Cl. H01L 31/0232; H01L 31/18

(52) U.S. Cl. 257/432; 438/69; 257/E31.127

(57) ABSTRACT

A solid-state imaging device includes: photodetection cells formed in a semiconductor substrate and including respective photodetection photoelectric conversion elements for detecting light coming form a subject; black level detection cells formed in the semiconductor substrate, for detecting a black level; and a light shield layer which is formed over an area where the photodetection cells and the black level detection cells are formed, has openings over the respective photodetection photoelectric conversion elements of the photodetection cells, has no openings over the black level detection cells, and has contact portions that are in contact with the semiconductor substrate, the contact portions being formed only in or in the vicinity of plan-view areas of the black level detection cells, respectively.

### CROSS-REFERENCE TO RELATED APPLICATIONS

This application claims the benefit of Japanese Patent Application JP 2009-023662, filed Feb. 4, 2009, the entire content of which is hereby incorporated by reference, the same as if set forth at length.

### FIELD OF THE INVENTION

The present invention relates to a solid-state imaging device, an imaging apparatus having it, and a manufacturing method of the solid-state imaging device.

### BACKGROUND OF THE INVENTION

Solid-state imaging devices such as CCD image sensors and CMOS image sensors are equipped with photodetection cells including photodetection photoelectric conversion elements for detecting light coming from a subject and black level detection cells including black level detection photoelectric conversion elements for detecting a black level of the photodetection cells. FIGS. 7A and 7B are schematic sectional views, including photodetection cells and black level detection cells, respectively, of a conventional CCD image sensor.

As shown in FIG. 7A, each photodetection cell includes a photodetection photoelectric conversion element 101 and a charge transfer member (a charge transfer channel C and transfer electrodes 104) for transferring charge that is generated in the photoelectric conversion element 101. Light shines on the photodetection photoelectric conversion elements 101, which are formed in a p-well layer which is formed in an n-type silicon substrate, through openings of a light shield layer W (made of tungsten or the like) that are formed over the respective photoelectric conversion elements 101.

As shown in FIG. 7B, each black level detection cell includes a black level detection photoelectric conversion element 102 and a charge transfer member (a charge transfer channel C and transfer electrodes 104) for transferring charge that is generated in the photoelectric conversion element 102. No light shines on the black level detection photoelectric conversion elements 102 because no openings are formed through the light shield layer W over the photoelectric conversion elements 102.

A high-concentration p-type impurity layer is formed in a surface portion of each of the photoelectric conversion elements 101 and 102 and serves to reduce a dark current which is caused by surface states etc.

To minimize smear which is noise specific to them, CCD image sensors are designed so that the distance between a light shield layer and a silicon substrate is made as short as possible. For example, in latest cells of approximately a 2-μm square, the equivalent oxide thickness of an insulating layer between a light shield layer and a silicon substrate is as small as about 100 nm which is about two times that of a gate insulating layer.

A general manufacturing process of the example configuration of FIGS. 7A and 7B is as follows. After elements are formed in a p-well layer, transfer electrodes 104 of polysilicon or the like are formed. An insulating layer 105 is formed on the above members and a light shield layer W is formed on the insulating layer 105. Then, an insulating layer 106 is formed on the light shield layer W and contact holes are formed through the insulating layer 106. Aluminum interconnections which are connected to the p-well layer are buried in the contact holes, whereby the potential of the light shield layer W is fixed to the ground potential.

In the above manufacturing process, a step of depositing an interlayer insulating layer, a step of forming contact holes, and other steps exist between the formation of the light shield layer and the connection of the light shield layer to the p-well layer. The light shield layer is in a floating state during that course. As a result, the light shield layer and the p-well layer may be given different potentials because of, for example, charging-up of the light-shield layer in those steps.

As described above, solid-state imaging devices that are highly increased in miniaturization have such a structure that the light shield layer, the silicon substrate, and the gate insulating layer formed between them cause a non-negligible parasitic MOS electric field effect because of the reduced distance between the light shield layer and the p-well layer, the potential difference between the light shield layer and the p-well layer, and other factors. An invention utilizing the parasitic MOS electric field effect is disclosed in JP-A-2003-37262. However, this structure has many problems.

In particular, a problem arises when this technique is applied to a case that the portions of the light shield layer W that correspond to the photodetection cells are different in structure from the portions of the light shield layer W that correspond to the black level detection cells (the photodetection cells and black level detection cells shown in FIGS. 7A and 7B are commonly used in the art). The black level detection cells for which no openings are formed through the light shield layer W are more vulnerable to the parasitic MOS electric field effect than the photodetection cells for which the openings are formed through the light shield layer W. Because of the difference in the vulnerability to the parasitic MOS electric field effect, the photodetection cells and the black level detection cells have different dark currents.

FIGS. 8A and 8B are image diagrams showing how the parasitic MOS effect depends on the structure of the light shield layer. In each of FIGS. 8A and 8B, hatched portions are portions where surface states are affected by the parasitic MOS effect. The thicker the hatched portion, the greater the influence.

The dark current occurring in each cell has a component that occurs in the photoelectric conversion element and a component that occurs in the charge transfer channel. As shown in FIGS. 7A and 7B and FIGS. 8A and 8B, the surface of each of the photoelectric conversion elements 101 and 102 is shielded by the p-type impurity layer. Therefore, even if the number of surface states is varied by the parasitic MOS effect, the resulting increase in the corresponding dark current component is slight and does not cause any serious problem. That is, although the photoelectric conversion elements 101 and the photoelectric conversion elements 102 are affected differently by the parasitic MOS effect, the dark currents occurring in these two kinds of photoelectric conversion elements have only a small difference.

On the other hand, the surface of each charge transfer channel C is not provided with a p-type impurity layer and hence is not shielded completely. Therefore, the dark current occurring in each charge transfer channel C is affected very much by a variation in the number of surface states. That is, the dark currents occurring in the charge transfer channels C of the photodetection cells are much different from those occurring in the charge transfer channels C of the black level detection cells because of the difference in the influence of the parasitic MOS effect.

For the above-described reason, the dark current occurring in the whole of each black level detection cell is larger than that occurring in the whole of each photodetection cell.

If larger dark currents occur in the black level detection cells in the above-described manner, an image darkening phenomenon that the whole of an image becomes darker occurs when it is generated by using, as a reference, signals that are obtained from the black level detection cells.

Conventionally, various configurations have been proposed to give the same potential to the light shield layer and the silicon substrate (refer to JP-A-63-142859, JP-A-7-94699, JP-A-11-177078, JP-A-2007-189022 and JP-A-2002-141490). However, none of these configurations can make the dark current difference between the photodetection cells and the black level detection cells sufficiently small. None of these documents even refer to the issue of making the dark current difference between the photodetection cells and the black level detection cells sufficiently small.

JP-A-63-142859 and JP-A-7-94699 employ a configuration that the substrate and the light shield layer are connected to each other in the pixel area where the photodetection cells are provided. However, in this configuration, it is difficult to avoid, for example, image quality degradation due to deterioration in transfer performance and to attain stable manufacture.

JP-A-11-177078, JP-A-2007-189022 and JP-A-2002-141490 employ configurations that the substrate and the light shield layer are connected to each other outside the pixel area, in the vicinity of the HCCD, or in a space that is located on the side opposite to the HCCD. However, in these configurations, sufficient stability of the characteristics of the entire pixel area may not be obtained depending on the difference between the time constants of the substrate and the light shield layer.

### SUMMARY OF THE INVENTION

The present invention has been made in the above circumstances, and an object of the invention is therefore to provide a solid-state imaging device capable of detecting a black level accurately, an imaging apparatus having it, and a manufacturing method of the solid-state imaging device.

A solid-state imaging device according to the invention comprises photodetection cells formed in a semiconductor substrate and including respective photodetection photoelectric conversion elements for detecting light coming form a subject; black level detection cells formed in the semiconductor substrate, for detecting a black level; and a light shield layer which is formed over an area where the photodetection cells and the black level detection cells are formed, has openings over the respective photodetection photoelectric conversion elements of the photodetection cells, has no openings over the black level detection cells, and has contact portions that are in contact with the semiconductor substrate, the contact portions being formed only in or in the vicinity of plan-view areas of the black level detection cells, respectively.

An imaging device according to the invention comprises the above solid-state imaging device.

A manufacturing method of a solid-state imaging device according to the invention comprises a first step of forming, in a semiconductor substrate, photodetection cells including respective photodetection photoelectric conversion elements for detecting light coming form a subject and black level detection cells for detecting a black level; a second step, executed after the first step, of forming openings through a material layer that covers the semiconductor substrate only in or in the vicinity of plan-view areas of the black level detection cells, respectively; and a third step of forming a light shield layer by depositing a light shield material so that it comes into contact with portions, exposed through the openings, of the semiconductor substrate and forming openings through the light shield material over the respective photoelectric conversion elements.

The invention can provide a solid-state imaging device capable of detecting a black level accurately, an imaging apparatus having it, and a manufacturing method of the solid-state imaging device.

### BRIEF DESCRIPTION OF THE DRAWINGS

FIG. 1 is a schematic plan view of a solid-state imaging device according to an embodiment of the present invention.

FIG. 2 is a schematic sectional view taken along line A-A′ in FIG. 1.

FIGS. 3A, 3B and 3C are schematic sectional views for description of a manufacturing method of the solid-state imaging device of FIG. 1.

FIG. 4 shows a first modification of the solid-state imaging device of FIG. 1.

FIG. 5 shows a second modification of the solid-state imaging device of FIG. 1.

FIG. 6 is a schematic sectional view taken along line B-B′ in FIG. 5.

FIGS. 7A and 7B are schematic sectional views of a conventional CCD image sensor.

FIGS. 8A and 8B show how a parasitic MOS effect affects photodetection cells and black level detection cells differently.

### DETAILED DESCRIPTION OF THE INVENTION

An embodiment of the present invention will be hereinafter described with reference to the drawings.

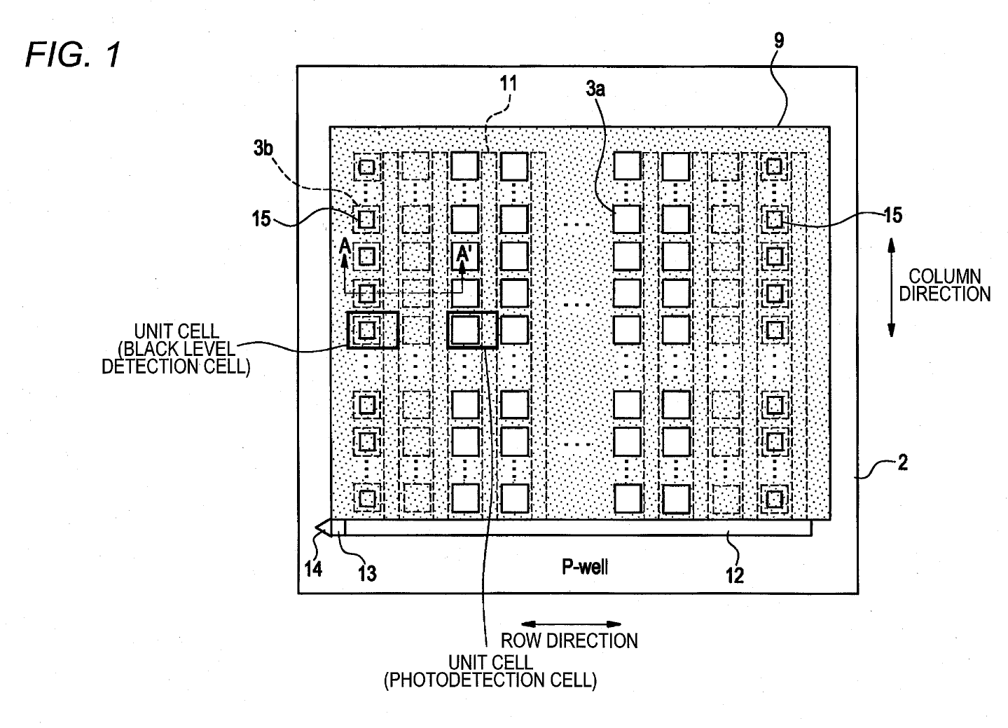

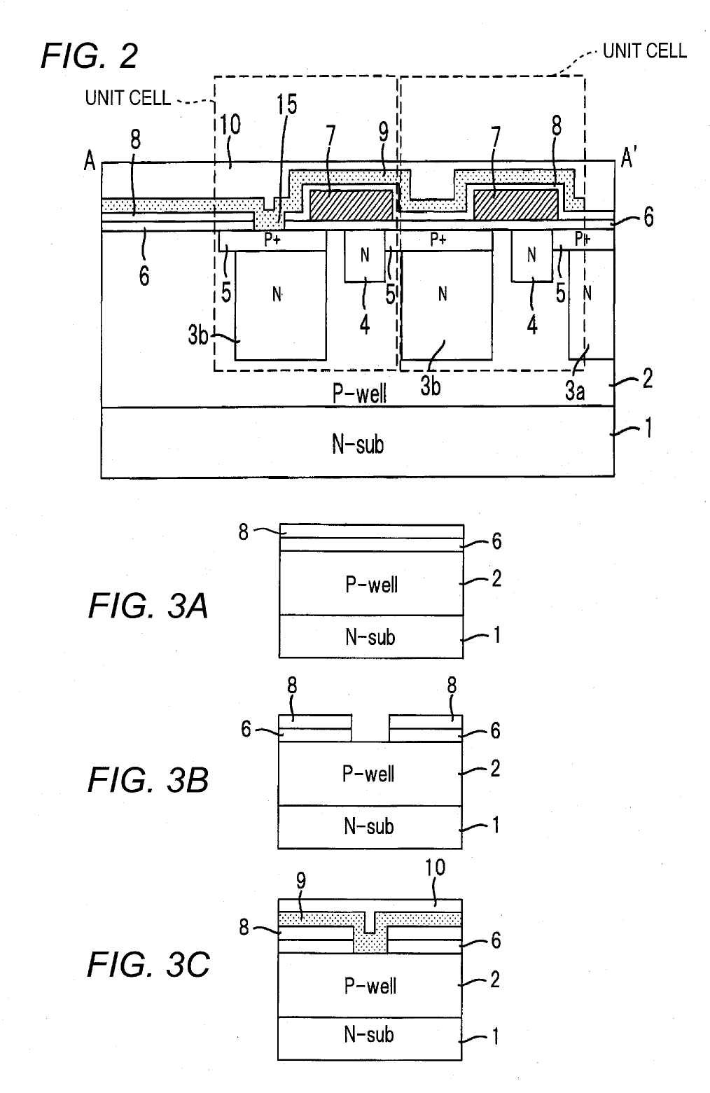

FIG. 1 is a schematic plan view of a solid-state imaging device according to the embodiment of the invention. FIG. 2 is a schematic sectional view taken along line A-A′ in FIG. 1. This solid-state imaging device is used being incorporated in an imaging apparatus that is built in a cell phone, an electronic endoscope, or the like or an imaging apparatus such as a digital camera or a digital video camera.

A p-well layer 2 is formed in an n-type silicon substrate 1 adjacent to its surface. Plural photoelectric conversion elements are formed in the p-well layer 2 so as to be arranged two dimensionally, that is, in a row direction and a column direction which is perpendicular to the row direction (in the example of FIG. 1, so as to assume a square lattice). The plural photoelectric conversion elements include photodetection photoelectric conversion elements 3a (indicated by solid lines in FIG. 1) for detecting light coming from a subject and black level detection photoelectric conversion elements 3b (indicated by broken lines in FIG. 1) for detecting a black level of the photodetection photoelectric conversion elements 3a.

Each photoelectric conversion element has an n-type impurity layer that is formed adjacent to the surface of the p-well layer 2. A photodiode (photoelectric conversion element) for generating charge in response to light and storing the generated charge is formed by the pn junction of the n-type impurity layer and the p-well layer 2. For dark current reduction and other purposes, a high-concentration p-type impurity layer 5 is formed in a surface portion of the n-type impurity layer.

The plural photoelectric conversion elements are arranged in such a manner that plural lines each of which consists of plural photoelectric conversion elements that are arranged in the row direction are arranged in the column direction. Each line includes black level detection photoelectric conversion elements 3b and photodetection photoelectric conversion elements 3a. In each line, two black level detection photoelectric conversion elements 3b, for example, are disposed at each end and plural photodetection photoelectric conversion elements 3a are disposed between those sets of black level detection photoelectric conversion elements 3b.

Charge that is generated in each photoelectric conversion element is read into an associated one of plural vertical charge transfer members 11 which are arranged in the column direction so as to correspond to the respective columns of photoelectric conversion elements, and is then transferred through the associated vertical charge transfer member 11. Each vertical charge transfer member 11 is composed of a charge transfer channel 4 which is an n-type impurity layer formed in the p-well 2 and a transfer electrode 7 which is formed over the charge transfer channel 4 with a gate insulating layer 6 interposed in between.

A horizontal charge transfer member 12 is provided adjacent to one ends of the plural vertical charge transfer members 11. The horizontal charge transfer member 12 transfers, in the row direction, charges that have been transferred from the vertical charge transfer members 11. A floating diffusion layer 13 is connected to one end of the horizontal charge transfer member 12 and a source follower amplifier 14 is connected to the floating diffusion layer 13. Charge that has been transferred through the horizontal charge transfer member 12 is converted into an output voltage signal that corresponds to the charge amount by the floating diffusion layer 13 and the source follower amplifier 14.

A light shield layer 9 made of tungsten or the like is formed over an area where the photodetection photoelectric conversion elements 3a, the black level detection photoelectric conversion elements 3b, and the vertical charge transfer members 11 are formed. Having openings only over the respective photodetection photoelectric conversion elements 3a, the light shield layer 9 shields the members other than the photodetection photoelectric conversion elements 3a from light and thereby prevents light from entering the black level detection photoelectric conversion elements 3b or the vertical charge transfer members 11.

The light shield layer 9 has contact portions 15 which are in contact with the p-well layer 2. The contact portions 15 are in contact with the p-well layer 2 because they are in contact with the surface p-type impurity layers 5 of part of the black level detection photoelectric conversion elements 3b (in the example of FIG. 1, the two black level detection photoelectric conversion elements 3b located at both ends of each line that extends in the row direction). Although in the embodiment the contact portions 15 are in contact with part of the black level detection photoelectric conversion elements 3b, the contact portions 15 may be in contact with the surfaces of all the black level detection photoelectric conversion elements 3b.

As shown in FIG. 2, the gate insulating layer 6 which is an ONO layer, an SiO₂ layer, or the like is formed on the p-well layer 2 and the transfer electrodes 7 made of polysilicon or the like are formed on the gate insulating layer 6. An insulating layer 8 which is an oxide layer, a nitride layer, or the like is formed on the transfer electrodes 7, and the light shield layer 9 is formed on the insulating layer 8. An oxide layer 10 which is a BPSG layer or the like is formed on the light shield layer 9, and intralayer lenses, color filters, and microlenses (none of those are shown) are formed on the oxide layer 10.

As shown in FIG. 2, openings are formed through the material layer (gate insulating layer 6 and insulating layer 8) over the selected ones of the black level detection photoelectric conversion elements 3b.

The solid-state imaging device of FIG. 1 is equipped with plural unit cells which are shown in FIGS. 1 and 2. The unit cells include photodetection cells and black level detection cells. Each photodetection cell includes a photodetection photoelectric conversion element 3a and part of the vertical charge transfer member 11 that is adjacent to the photodetection photoelectric conversion element 3a and serves to read charge from it. Each black level detection cell includes a photodetection photoelectric conversion element 3b and part of the vertical charge transfer member 11 that is adjacent to the photodetection photoelectric conversion element 3b and serves to read charge from it. The black level detection cells are cells that are provided to detect a dark current (black level) that occurs when none of the photodetection cells are receiving light.

Next, a manufacturing method of the above-configured solid-state imaging device will be described.

FIGS. 3A-3C are schematic sectional views for description of a manufacturing method of the solid-state imaging device of FIG. 1. First, photodetection cells and black level detection cells are formed by forming a device area including a p-well layer 2, photoelectric conversion elements 3a and 3b, charge transfer channels 4, p-type impurity layers 5, a gate insulating layer 6 (ONO layer), transfer electrodes 7, etc. in an n-type silicon substrate 1 (n-type epitaxially grown layer). Then, an insulating layer 8 is deposited by thermal CVD (HTO), thermal TEOS-CVD, or the like. The structure of FIG. 3A is thus completed. The device members formed in the p-well layer 2 are omitted in FIGS. 3A to 3C.

Then, contact holes are formed through the material layer (gate insulating layer 6 and insulating layer 8) that covers the p-well layer 2 only over part of the black level detection cells (e.g., only over part of the photoelectric conversion elements 3b) by resist patterning and etching, whereby portions of the p-well layer are exposed (see FIG. 3B).

Then, a light shield layer 9 is formed by depositing a tungsten layer by CVD or PVD and forming openings only over the photodetection photoelectric conversion elements 3a by photolithography and etching. As a result of this step, the light shield layer 9 comes into contact with the p-well layer 2 through the contact holes to form contact portions 15. Since the light shield layer 9 comes into contact with the p-well layer 2 when it is formed, the potentials of the light shield layer 9 and the p-well layer 2 will be kept the same during the ensuing manufacturing process. The light shield layer 9 may be a stack of a tungsten layer and a titanium nitride layer or a stack of a tungsten layer, a titanium nitride layer, and a titanium layer. The light shield layer 9 may have some other layer structure as long as it exhibits necessary light shield performance and conductivity.

Then, a BPSG, thermal TEOS, plasma TEOS, HDP-SiO, SOG, or like oxide layer 10 (interlayer insulating layer) that is high in buriability and flatness is deposited, whereby the structure of FIG. 3C is completed. The oxide layer 10 may be a single layer, a stack, or a layer formed by a combination of several deposition methods. It may be replaced by an insulating layer other than an oxide layer.

Then, contact hole formation, metal deposition, resist patterning, and etching are performed. This metal layer is not shown in FIG. 3C because in the area shown in FIG. 3C the metal layer is removed completely after the deposition. Usually, the metal layer is deposited by sputtering Al or an Al alloy such as AlSiCu. The metal layer may be a single layer or a stack. And the metal layer may have a barrier metal structure such as TiN/Ti, a silicide structure such as TiN/Ti/TiSi, a sandwich structure using a barrier metal such as TiN, or the like. As such, the structure of the metal layer is not limited to any structure as long as it is a common metal structure.

Then, a device (not shown) is completed by forming elements of a common optical system such as downward convex intralayer lenses, upward convex intralayer lenses, a planarization layer, color filters, and microlenses. These optical system elements are not indispensable, that is, whether each of these (sets of) optical system elements should be provided is determined according to the use and the necessary performance of an image sensor intended.

As described above, in the solid-state imaging device of FIG. 1, the light shield layer 9 and the p-well layer 2 are given the same potential at the same time as the light shield layer 9 is formed. Therefore, a parasitic MOS electric field effect can be suppressed that is caused by ensuing manufacturing steps. Furthermore, since the light shield layer 9 and the p-well layer 2 are in contact with each other only via the surfaces of part of the black level detection cells which are more vulnerable to the parasitic MOS electric field effect, the parasitic MOS electric field effect is suppressed more in the black level detection cells. As a result, the degree of influence of the parasitic MOS electric field effect on the photodetection cells can be made approximately equal to that on the black level detection cells. This makes it possible to detect a black level accurately and hence to increase the image quality.

Although the above description is directed to the case that the solid-state imaging device is of a CCD type, it may be of a CMOS type. The arrangement of the photoelectric conversion elements is not limited to a square lattice and may be what is called a honeycomb arrangement in which the photoelectric conversion elements on the odd-numbered lines among the lines shown in FIG. 1 are shifted from those on the even-numbered lines in the row direction by ½ of the arrangement pitch of the photoelectric conversion elements. Although the above description is directed to the configuration in which the carriers are electrons, FIGS. 1 to 3A-3C and the related descriptions are also applicable to the case that the carriers are holes if the conductivity types “n” and “p” are interchanged.

In the above description, the black level detection photoelectric conversion elements 3b have the same structure as the photodetection photoelectric conversion elements 3a and the photodetecting surfaces of the former are shielded from light. However, in general, in each cell, the dark current is much larger in the charge transfer channel whose surface is not shielded by a high-concentration p-type impurity layer than in the photoelectric conversion element whose surface is shielded by the high-concentration p-type impurity layer 5. Although the black level detection cells are for detection of a black level of the photodetection cells, in each cell a large part of the dark current occurs in the charge transfer channel. Therefore, it is not always necessary to form the black level detection photoelectric conversion elements 3b. For example, a configuration is possible in which no n-type impurity layer is formed in each region where a black level detection photoelectric conversion element 3b should be formed, that is, a p-type impurity layer 5 and a portion of the p-well layer 2 are formed in each such region.

It is inferred that a parasitic MOS electric field effect would occur when the thickness of the insulating layer formed between the light shield layer 9 and the n-type silicon substrate 1 is less than or equal to 200 nm in terms of the equivalent oxide thickness. Therefore, the configuration of FIGS. 1 and 2 is particularly effective in solid-state imaging devices in which the thickness of the insulating layer is less than or equal to 200 nm in terms of the equivalent oxide thickness.

Next, modifications of the solid-state imaging device of FIG. 1 will be described.

### (First Modification)

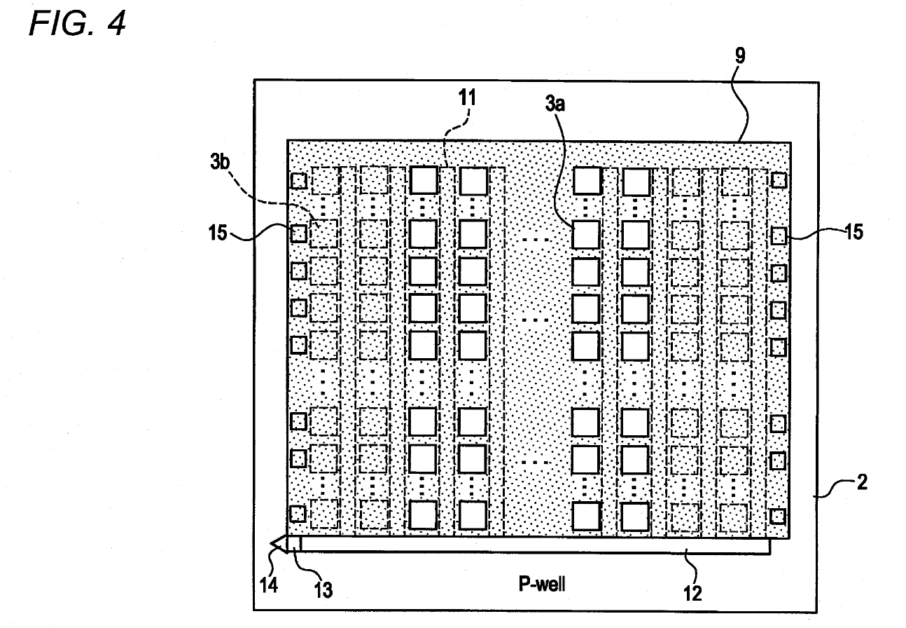

FIG. 4 shows a first modification of the solid-state imaging device of FIG. 1. The solid-state imaging device of FIG. 4 is different from that of FIG. 1 in that the contact portions 15 of the light shield layer 9 are formed in spaces that are located outside the area where the black level detection cells are formed rather than on the surfaces of the black level detection photoelectric conversion elements 3b. In this case, the contact portions 15 are in contact with the p-well layer through openings formed through the gate insulating layer 6 and the insulating layer 8.

The manufacturing method of the solid-state imaging device of FIG. 4 is approximately the same as that of the solid-state imaging device of FIG. 1. More specifically, after photodetection cells and black level detection cells are formed in the n-type silicon substrate 1, openings are formed through those parts of the insulating layer 8 and the gate insulating layer 6 which are located in the above-mentioned spaces. The openings are filled with a light shield layer 9, whereby the light shield layer 9 comes into contact with the p-well layer 2.

Also in the configuration of FIG. 4, the light shield layer 9 and the p-well layer 2 are in contact with each other in the vicinity of the black level detection cells and are not in contact with each other in the vicinity of the photodetection cells. Therefore, the degree of influence of the parasitic MOS electric field effect on the black level detection cells can be made approximately equal to that on the photodetection cells. As a result, no large difference in dark current occurs between the black level detection cells and photodetection cells. The black level detection can thus be performed accurately.

As shown in FIGS. 1 and 4, satisfactory results are obtained as long as the contact portions 15 are located in or in the vicinity of the black level detection cells. The term “in the vicinity of” refers to such a range that the distance between each contact portion 15 and the closest photodetection cell is longer than the distance between it and the closest black level detection cell.

The configuration of FIG. 4 enables contact between the light shield layer 9 and the semiconductor substrate without disordering the repetitive structure in the area where the photoelectric conversion elements are provided. As a result, deterioration of the charge transfer performance of the vertical charge transfer members 11 and other problems can be prevented and the image quality can be increased. On the other hand, the configuration of FIG. 1 is advantageous over the configuration of FIG. 4 in that the chip size can be reduced.

### (Second Modification)

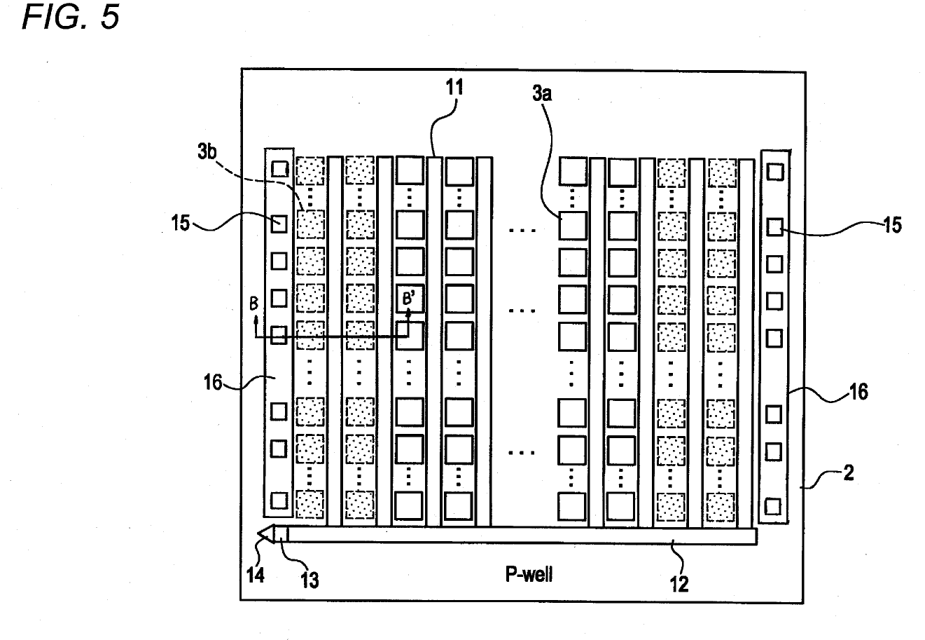

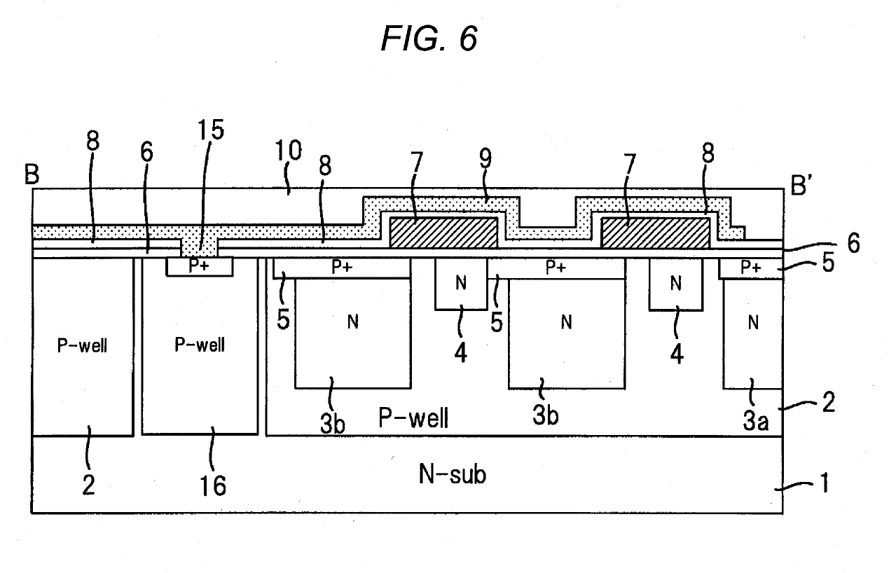

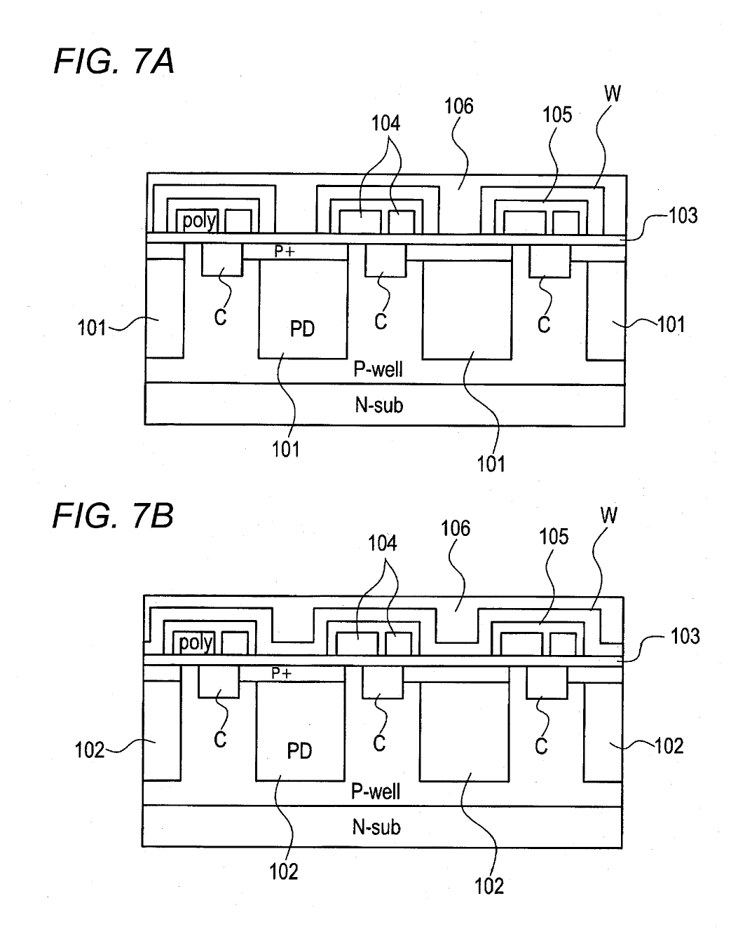

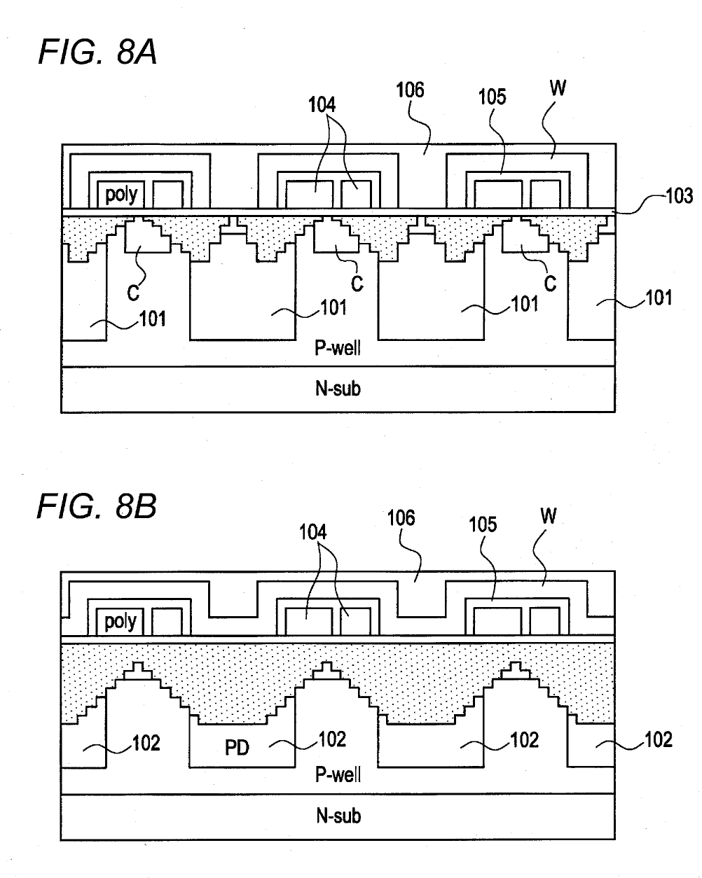

FIG. 5 shows a second modification of the solid-state imaging device of FIG. 1. Unlike in FIG. 1, the light shield layer 9 is omitted in FIG. 4. FIG. 6 is a schematic sectional view taken along line B-B′ in FIG. 5.

The solid-state imaging device of FIG. 5 is different from that of FIG. 4 in that p-well layers 16 are formed separately from the p-well layer 2 in spaces that are located outside the area where the black level detection cells are formed. As shown in FIG. 6, the contact portions 15 are in contact with the p-well layers 16 through openings that are formed through the gate insulating layer 6 and the insulating layer 8. Satisfactory results are obtained as long as the contact portions 15 are formed in the vicinity of the black level detection cells. To establish ohmic contact between the p-well layers 16 and the contact portions 15, it is preferable that as shown in FIG. 6 p-type impurity layers be formed adjacent to the surface of each p-well layer 16 and brought into contact with the respective contact portions 15.

The manufacturing method of the solid-state imaging device of FIG. 5 is approximately the same as that of the solid-state imaging device of FIG. 1. More specifically, after a p-well layer 2 and p-well layers 16 are formed in the n-type silicon substrate 1 so as to be spaced from each other, black level detection photoelectric conversion elements 3b, photodetection photoelectric conversion elements 3a, and their peripheral members are formed in the p-well layer 2. After formation of transfer electrodes 7 and an insulating layer 8, openings are formed through those parts of the insulating layer 8 and the gate insulating layer 6 which are located over the p-well layers 16. The openings are filled with a light shield layer 9, whereby the light shield layer 9 comes into contact with the p-well layers 16.

In the solid-state imaging device of FIG. 5, the n-type silicon of the n-type silicon substrate 1 exists between the p-well layers 16 and the p-well layer 2 and a parasitic pnp bipolar structure is formed there. Therefore, the p-well layers 16 and the p-well layer 2 are given the same potential. Since the p-well layers 16 is in contact with the light shield layer 9, the p-well layer 2 and the light shield layer 9 can always be kept at the same potential during manufacture of the solid-state imaging device. This makes it possible to suppress occurrence of a parasitic MOS electric field effect.

When the solid-state imaging device of FIG. 5 is used, the potentials of the light shield layer 9 and the p-well layer 2 can be controlled independently. This makes it possible to use the technique of controlling the potential of the light shield layer 9 variably (as described in JP-A-2003-37262). It is possible to make use of advantages obtained by utilizing a parasitic MOS electric field effect.

As described above, the following items are disclosed in the specification:

The disclosed solid-state imaging device comprises photodetection cells formed in a semiconductor substrate and including respective photodetection photoelectric conversion elements for detecting light coming form a subject; black level detection cells formed in the semiconductor substrate, for detecting a black level; and a light shield layer which is formed over an area where the photodetection cells and the black level detection cells are formed, has openings over the respective photodetection photoelectric conversion elements of the photodetection cells, has no openings over the black level detection cells, and has contact portions that are in contact with the semiconductor substrate, the contact portions being formed only in or in the vicinity of plan-view areas of the black level detection cells, respectively.

With this configuration, since the light shield layer and the semiconductor substrate are in contact with each other only in or in the vicinity of the plan-view areas of the black level detection cells which are more vulnerable to the parasitic MOS electric field effect, the black level detection cells can be made less vulnerable to the parasitic MOS electric field effect. As a result, the degree of influence of the parasitic MOS electric field effect on the photodetection cells can be made approximately equal to that on the black level detection cells. This makes it possible to detect a black level accurately and hence to increase the image quality.

Where the contact portions are formed outside the plan-view areas of the black level detection cells, the repetitive structure of the pixels can be maintained and degradation of the image quality due to deterioration of the charge transfer performance and other factors can be prevented.

Where the contact portions are formed in the plan-view areas of the black level detection cells, the image quality can be increased without increasing the chip size.

The disclosed solid-state imaging device further comprises a first well layer formed in the semiconductor substrate and having a conductivity type that is opposite to a conductivity type of the semiconductor substrate; and a second well layer formed in the semiconductor substrate and having the conductivity type that is opposite to the conductivity type of the semiconductor substrate, wherein the photodetection cells and the black level detection cells are formed in the first well layer, and wherein the contact portions are in contact with the second well layer.

This configuration makes it possible to variably control the potential of the light shield layer while the solid-state imaging device is being driven. Furthermore, the light shield layer and the first well layer can be given either the same potential or different potentials during manufacture of the solid-state imaging device. Where they are given different potentials, influence of a plasma surge etc. can be suppressed by, for example, setting the potential difference between the light shield layer and the first well layer smaller than the breakdown voltage of a gate insulating layer formed on the semiconductor substrate during manufacture. As a result, the parasitic MOS electric field effect can be suppressed and the image quality can be increased by detecting a black level accurately.

The disclosed solid-state imaging device further comprises an insulating layer which is formed between the semiconductor substrate and the light shield layer and has a thickness that is less than or equal to 200 nm in terms of an equivalent oxide thickness.

The disclosed imaging device comprises one of the above solid-state imaging devices.

An embodiment of the disclosed manufacturing method of a solid-state imaging device comprises a first step of forming, in a semiconductor substrate, photodetection cells including respective photodetection photoelectric conversion elements for detecting light coming form a subject and black level detection cells for detecting a black level; a second step, executed after the first step, of forming openings through a material layer that covers the semiconductor substrate only in or in the vicinity of plan-view areas of the black level detection cells, respectively; and a third step of forming a light shield layer by depositing a light shield material so that it comes into contact with portions, exposed through the openings, of the semiconductor substrate and forming openings through the light shield material over the respective photoelectric conversion elements.

Another embodiment of the disclosed manufacturing method of a solid-state imaging device comprises a first step of forming, in a semiconductor substrate, photodetection cells including respective photodetection photoelectric conversion elements for detecting light coming form a subject and black level detection cells for detecting a black level; a second step, executed after the first step, of forming openings through a material layer that covers the semiconductor substrate in spaces that are located outside the area where the black level detection cells are formed; and a third step of forming a light shield layer by depositing a light shield material so that it comes into contact with portions, exposed through the openings, of the semiconductor substrate and forming openings through the light shield material over the respective photoelectric conversion elements.

The disclosed manufacturing method of a solid-state imaging device further comprises the steps of forming, in the semiconductor substrate, a first well layer having a conductivity type that is opposite to a conductivity type of the semiconductor substrate; and forming, in the semiconductor substrate, a second well layer having the conductivity type that is opposite to the conductivity type of the semiconductor substrate, wherein the first step forms the photodetection cells and the black level detection cells in the first well layer, and wherein the second step forms the openings in a plan-view area of the second well layer.

The disclosed manufacturing method of a solid-state imaging device further comprises the step of forming an insulating layer between the semiconductor substrate and the light shield layer at a thickness that is less than or equal to 200 nm in terms of an equivalent oxide thickness.

What is claimed is:

1. A solid-state imaging device comprising:
photodetection cells formed in a semiconductor substrate and comprising respective photodetection photoelectric conversion elements for detecting light coming form a subject;
black level detection cells formed in the semiconductor substrate, for detecting a black level; and
a light shield layer which is formed over an area where the photodetection cells and the black level detection cells are formed, has openings over the respective photodetection photoelectric conversion elements of the photodetection cells, has no openings over the black level detection cells, and has contact portions that are in contact with the semiconductor substrate, the contact portions being formed only in or in the vicinity of plan-view areas of the black level detection cells, respectively.

2. A solid-state imaging device comprising:
photodetection cells formed in a semiconductor substrate and comprising respective photodetection photoelectric conversion elements for detecting light coming form a subject;
black level detection cells formed in the semiconductor substrate, for detecting a black level; and
a light shield layer which is formed over an area where the photodetection cells and the black level detection cells are formed, has openings over the respective photodetection photoelectric conversion elements of the photodetection cells, has no openings over the black level detection cells, and has contact portions that are in contact with the semiconductor substrate, the contact portions being formed in spaces that are located outside the area where the black level detection cells are formed.

3. The solid-state imaging device according to claim 1, wherein the contact portions are formed only in plan-view areas of the black level detection cells, respectively.

4. The solid-state imaging device according to claim 1, further comprising:
a first well layer formed in the semiconductor substrate and having a conductivity type that is opposite to a conductivity type of the semiconductor substrate; and
a second well layer formed in the semiconductor substrate and having the conductivity type that is opposite to the conductivity type of the semiconductor substrate, wherein:
the photodetection cells and the black level detection cells are formed in the first well layer; and
the contact portions are in contact with the second well layer.

5. The solid-state imaging device according to claim 1, further comprising an insulating layer provided between the semiconductor substrate and the light shield layer, wherein the insulating layer has a thickness that is less than or equal to 200 nm in terms of an equivalent oxide thickness.

6. An imaging apparatus comprising the solid-state imaging device according to claim 1.

7. A manufacturing method of a solid-state imaging device, comprising:
a first step of forming, in a semiconductor substrate, photodetection cells comprising respective photodetection photoelectric conversion elements for detecting light coming form a subject and black level detection cells for detecting a black level;
a second step, after the first step, of forming openings through a material layer that covers the semiconductor substrate only in or in the vicinity of plan-view areas of the black level detection cells, respectively; and
a third step of forming a light shield layer by depositing a light shield material so that it comes into contact with portions, exposed through the openings, of the semiconductor substrate and forming openings through the light shield material over the respective photoelectric conversion elements.

8. A manufacturing method of a solid-state imaging device, comprising:
a first step of forming, in a semiconductor substrate, photodetection cells comprising respective photodetection photoelectric conversion elements for detecting light coming form a subject and black level detection cells for detecting a black level;
a second step, after the first step, of forming openings through a material layer that covers the semiconductor substrate in spaces that are located outside the area where the black level detection cells are formed; and
a third step of forming a light shield layer by depositing a light shield material so that it comes into contact with portions, exposed through the openings, of the semiconductor substrate and forming openings through the light shield material over the respective photoelectric conversion elements.

9. The manufacturing method of a solid-state imaging device according to claim 7, wherein in the second step, openings are formed through a material layer that covers the semiconductor substrate only in plan-view areas of the black level detection cells, respectively.

10. The manufacturing method of a solid-state imaging device according to claim 7, further comprising the steps of:
forming, in the semiconductor substrate, a first well layer having a conductivity type that is opposite to a conductivity type of the semiconductor substrate; and
forming, in the semiconductor substrate, a second well layer having the conductivity type that is opposite to the conductivity type of the semiconductor substrate, wherein:
the first step forms the photodetection cells and the black level detection cells in the first well layer; and
the second step forms the openings in a plan-view area of the second well layer.

11. The manufacturing method of a solid-state imaging device according to claim 7, further comprising the step of forming an insulating layer between the semiconductor substrate and the light shield layer at a thickness that is less than or equal to 200 nm in terms of an equivalent oxide thickness.
